(19) United States
(12) Patent Application Publication
(10) Pub. No.: US 2025/0204082 A1
(43) Pub. Date: Jun. 19, 2025

(54) SILICON-BASED ROOM-TEMPERATURE INFRARED HOT-ELECTRON PHOTODETECTOR, METHOD FOR PREPARING SAME, AND USE OF SAME

(71) Applicant: SOOCHOW UNIVERSITY, Wujiang (CN)

(72) Inventors: Cheng ZHANG, Wujiang (CN); Chenghan Wu, Wujiang (CN); Binglin Huang, Wujiang (CN); Xiaofeng Li, Wujiang (CN); Shaojun Wang, Wujiang (CN); Zefeng Chen, Wujiang (CN)

(21) Appl. No.: 18/731,093

(22) Filed: May 31, 2024

(30) Foreign Application Priority Data
Dec. 14, 2023 (CN) 202311721584.7

(51) Int. Cl. H01L 31/0232; H01L 31/0216; H01L 31/0224; H01L 31/028; H01L 31/108; H01L 31/18

(52) U.S. Cl. CPC H10F 77/413; H10F 30/227; H10F 71/121; H10F 77/122; H10F 77/206; H10F 77/306

(57) ABSTRACT

The invention provides a silicon-based room-temperature infrared hot-electron photodetector, preparation method and use thereof. The photodetector includes a base and a planar multi-layer structure. The planar multi-layer structure includes a bottom conductive electrode, a silicon film, a transition metal film, and a transparent dielectric film. The electrode and the silicon film form an ohmic contact and constitute an optical reflector. The silicon film and the transition metal film form a Schottky contact, the thickness of the silicon film is smaller than the depletion layer width of a Schottky junction formed by the silicon film and the transition metal film, the transition metal film absorbs near infrared light and generates hot electrons to be injected into the silicon film, and the hot electrons are collected by the electrode to form a photocurrent. The transparent dielectric film is used as an antireflection layer and can reduce reflection of incident light.

### FIELD OF THE INVENTION

The present invention relates to the field of photodetection technologies, and in particular, to a silicon-based room-temperature infrared hot-electron photodetector, a method for preparing the same, and use of the same.

### DESCRIPTION OF THE RELATED ART

Because a silicon material is transparent to an infrared band lower than an energy band gap, a silicon photodetector has working wavelength restrictions and cannot implement photodetection in this band, referring to the literature: [Nanophotonics, 2016, 5 (1): 96-111]. Metal has no energy band gap, and therefore metal may be used to absorb hot electrons generated by infrared light to implement infrared photon energy detection lower than a silicon band gap, referring to the literature: [Nanophotonics, 2017, 6 (1): 177-191], so that a response band of a silicon photodetection system can be extended. A photodetector that uses a Schottky junction formed by a contact between metal and silicon to collect hot electrons has advantages such as a wide working band and adjustable polarization dependence, and therefore has acquired wide application and attention, referring to the literature: [Nature Nanotechnology, 2015, 10 (1): 25-34]. However, because conventional noble metal such as gold and silver has a high reflectivity, a generation rate of hot electrons and photoelectric conversion efficiency in the device are very low.

How to improve light absorption efficiency and hot electron transport and collection efficiency of metal becomes the key that restricts the responsivity in a hot-electron photodetector. In existing technologies:

For example, LiJian Zhang et al. have increased the absorption rate and responsivity by using a height-asymmetric integrated grating structure, referring to the literature: [Appl.Phys.Lett. 122, 031101 (2023)]. In addition, Cheng Zhang et al. have designed a gold-coated silicon nanometer conical structure, referring to the literature: [Adv.Funct.Mater. 2023, 2304368], and a hybrid plasma mode along a conical needlepoint provides great field enhancement and wideband response. In addition, Chinese Patent Publication No. CN113097335B and titled “Waveguide-coupled Plasma-enhanced Ge-based Infrared Photodetector and Method for Preparing Same” proposes the use of a waveguide structure and a metal grating on a silicon on insulator (SOI) to implement double absorption including Ge intrinsic absorption and hot electron absorption in a metal grating, so that an absorption range is expanded. In another example, in Chinese Patent Publication No. CN115411188A and tilted “Method for Preparing Metal Nanometer Particle Plasma Excimer Enhanced Single-walled Carbon Nanotube Film/Silicon Heterojunction-based Infrared Photodetector”, the resonance of plasma excimers generated by nanometer metal particles under photoexcitation is used to greatly improve the generation efficiency of electron-hole pairs, thereby improving the responsivity of the device.

However, micro and nano structures are used in all these existing technologies, and have extremely high processing requirements in nanotechnology, high costs, and are not applicable to actual application environments.

### SUMMARY OF THE INVENTION

In view of this, a technical problem to be resolved by the present invention is to overcome the problem in the prior art that photodetectors prepared using micro and nano structures have extremely high processing requirements and high costs, and provide a silicon-based room-temperature infrared hot-electron photodetector, a method for preparing the same, and use of the same. The photodetector has advantages such as wideband absorption, a simple structure, and a quick response speed, helps to improve the performance of a near infrared band photodetector, and can be applied to near infrared band imaging and communication.

To resolve the foregoing technical problems, the present invention provides a silicon-based room-temperature infrared hot-electron photodetector, including a base and a planar multi-layer structure disposed on the base. The planar multi-layer structure includes:
a bottom conductive electrode;
a silicon thin film, disposed on the bottom conductive electrode, where the bottom conductive electrode and the silicon thin film form an ohmic contact and constitute an optical reflector;
a transition metal film, disposed on the silicon thin film, where the silicon thin film and the transition metal film form a Schottky contact, a thickness of the disposed silicon thin film is smaller than a depletion layer width of a Schottky junction formed by the silicon substrate and the transition metal film, the transition metal film absorbs near infrared light and generates hot electrons to be injected into the silicon thin film, and the hot electrons are collected by the bottom conductive electrode to form a photocurrent; and
a transparent dielectric film, disposed on the transition metal film, where the transparent dielectric film is used as an antireflection layer and capable of reducing reflection of incident light.

In an embodiment of the present invention, the bottom conductive electrode includes a titanium film, a gold film, and an aluminum film. The thickness of the titanium film is greater than 5 nm, the thickness of the gold film is greater than 40 nm, and the thickness of the aluminum film is greater than 30 nm.

In an embodiment of the present invention, the material of the bottom conductive electrode is selected from the group consisting of gold, silver, chromium, aluminum, a noble metal, a transition metal and any combination thereof.

In an embodiment of the present invention, the silicon thin film is a lightly doped N-type or P-type silicon thin film, a resistivity of the silicon thin film ranges from 0.1 Ω·cm to 100 Ω·cm, and the thickness of the silicon thin film ranges from 10 nm to 5 μm.

In an embodiment of the present invention, a material of the transition metal film is selected from the group consisting of gold, platinum, iron, chromium, titanium and any combination thereof.

In an embodiment of the present invention, a thickness of the transition metal film ranges from 5 nm to 100 nm.

In an embodiment of the present invention, a material of the transparent dielectric film is selected from the group consisting of magnesium fluoride, silicon nitride, silicon oxide, PMMA and any combination thereof.

In an embodiment of the present invention, the thickness of the transparent dielectric film ranges from 50 nm to 500 nm.

To resolve the foregoing technical problems, the present invention provides a method for preparing a silicon-based room-temperature infrared hot-electron photodetector, including the following steps:
S1. placing a SOI (Silicon-On-Insulator) substrate in a hydrofluoric acid solution to remove a silicon oxide layer, to obtain a silicon thin film suspended in the solution;
S2. transferring the silicon thin film onto a target substrate, and performing drying treatment;
S3. depositing an aluminum film on a surface of the silicon thin film through vacuum coating, to obtain a dual-film structure consisting of the aluminum and silicon thin films;
S4. transferring the structure obtained in steps S3 into an organic solvent for standing;
S5. transferring the structure floating in the organic solvent onto a titanium gold electrode and performing drying;
S6. depositing a titanium film on the silicon thin film of the structure obtained in Step S5 through vacuum coating, wherein the titanium gold electrode and the aluminum film form a bottom conductive electrode on one side of the silicon thin film, and the titanium film forms a transition metal film on the other side of the silicon thin film; and
S7. spin-coating at least one of magnesium fluoride, silicon nitride, silicon oxide and PMMA on the transition metal film to form a transparent dielectric film.

To resolve the foregoing technical problems, the present invention further provides use of a silicon-based room-temperature infrared hot-electron photodetector. The foregoing silicon-based room-temperature infrared hot-electron photodetector is used, and the photodetector is applied to optical communication and near infrared imaging.

Compared with the prior art, the foregoing technical solution of the present invention has the following advantages:

The silicon-based room-temperature infrared hot-electron photodetector of the present invention has advantages such as wideband absorption, a simple structure, and a quick response speed, helps to improve the performance of a near infrared band photodetector, and can be applied to near infrared band imaging and communication.

A planar multi-layer structure is used as a wideband absorption device of a near infrared band, which is insensitive to polarization and insensitive to an incident angle, and has a large tolerance for a thickness error of a multi-layer film, so that requirements of processing technologies are not very high, preparation is easy, costs are low, and promotion and use are convenient.

The thickness of the silicon thin film is smaller than the depletion layer width of a Schottky junction formed by the silicon thin film and the transition metal film, which is conducive to collection of electrons.

Through the use of the transition metal film, efficient wideband absorption of a near infrared band from 1200 nm to 2000 nm is implemented, so that the generation efficiency of hot electrons is improved. In addition, the thermo-chemical loss of hot electrons in a transmission process can be greatly reduced, so that the collection efficiency of electrons is improved.

In addition, experiments verify and show that the silicon-based room-temperature infrared hot-electron photodetector of the present invention has the highest responsivity of 513 nA/mW in a band from 1200 nm to 1800 nm, and has a light response throughout 1200 nm to 1800 nm. A 1310-nm single-mode laser is used to test the response time. A rising edge and a falling edge of the photodetector are respectively 55 μs and 58 μs. Such response is ultra-fast.

### BRIEF DESCRIPTION OF THE DRAWINGS

To make the content of the present invention clearer and more comprehensible, the present invention is further described in detail below according to specific embodiments of the present invention and the accompanying draws. Where:

FIG. 1 is a schematic cross-sectional view of a silicon-based room-temperature infrared hot-electron photodetector according to the present invention;

FIG. 2 is a cross-sectional SEM image of a silicon-based room-temperature infrared hot-electron photodetector according to the present invention;

FIG. 3 is a diagram of an absorption reflectivity curve of a silicon-based room-temperature infrared hot-electron photodetector under a test by a spectrometer according to the present invention;

FIG. 4 is a current-voltage curve of a silicon-based room-temperature infrared hot-electron photodetector according to the present invention;

FIG. 5 is a diagram of a photocurrent-time curve of a silicon-based room-temperature infrared hot-electron photodetector under irradiation of laser light with different wavelengths according to the present invention;

FIG. 6 is a diagram of a responsivity curve of a silicon-based room-temperature infrared hot-electron photodetector in a near infrared band from 1200 nm to 1800 nm band according to the present invention;

FIG. 7 shows a response time of a silicon-based room-temperature infrared hot-electron photodetector under a laser test of 1310 nm according to the present invention;

FIG. 8 is a flowchart of a method for preparing a silicon-based room-temperature infrared hot-electron photodetector according to the present invention;

FIG. 9 is a schematic diagram of a test platform for the application of a silicon-based room-temperature infrared hot-electron photodetector in optical communication according to the present invention;

FIG. 10 shows a test result of an application of a silicon-based room-temperature infrared hot-electron photodetector to optical communication according to the present invention;

FIG. 11 is a schematic diagram of a test platform for the application of a silicon-based room-temperature infrared hot-electron photodetector in near infrared band imaging according to the present invention; and

FIG. 12 is a diagram of a test result of the application of a silicon-based room-temperature infrared hot-electron photodetector in near infrared band imaging according to the present invention.

Reference numerals: 1. bottom conductive electrode; 2. ultra-thin silicon thin film; 3. transition metal film; and 4. transparent dielectric film.

### DETAILED DESCRIPTION OF THE PREFERRED EMBODIMENTS

The present invention is further described below with reference to the accompanying drawings and specific embodiments, to enable a person skilled in the art to better understand and implement the present invention. However, the embodiments are not used to limit the present invention.

### Embodiment 1

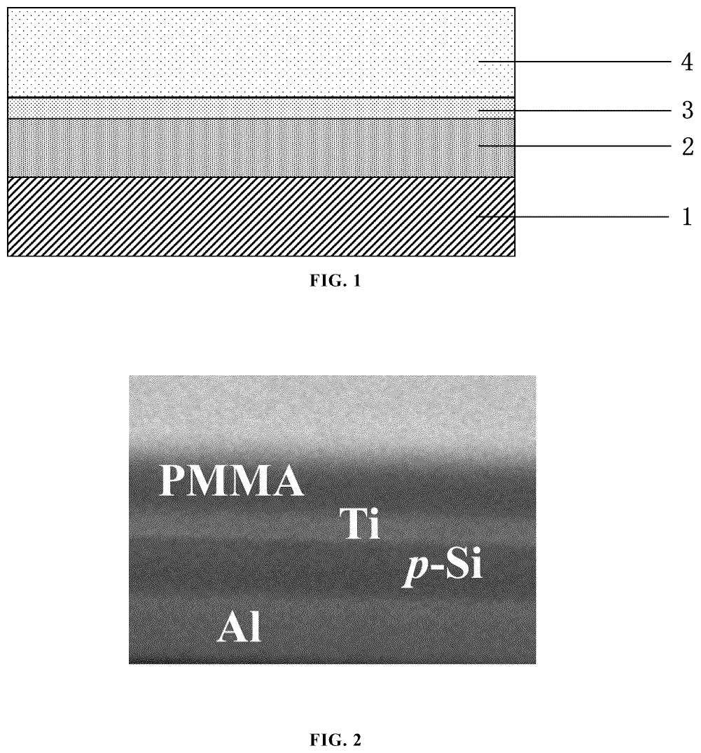

Referring to FIG. 1, the present invention provides a silicon-based room-temperature infrared hot-electron photodetector, including a base and a planar multi-layer structure disposed on the base. The planar multi-layer structure sequentially includes from bottom to top: a bottom conductive electrode 1, a silicon thin film 2, a transition metal film 3, and a transparent dielectric film 4. The bottom conductive electrode 1 is connected to the base. The silicon thin film 2 is disposed on the bottom conductive electrode 1. The bottom conductive electrode 1 and the silicon thin film 2 form an ohmic contact and constitute an optical reflector, so that the light absorption efficiency of transition metal can be improved. The transition metal film 3 is disposed on the silicon thin film 2. The silicon thin film 2 and the transition metal film 3 form a Schottky contact. The thickness of the silicon thin film 2 is smaller than a depletion layer width of a Schottky junction formed by the silicon thin film 2 and the transition metal film 3, which is conducive to the collection of electrons. The transition metal film 3 absorbs near infrared light and generates hot electrons to be injected into the silicon thin film 2. The hot electrons are collected by a bottom electrode to form a photocurrent. The transparent dielectric film 4 is disposed on the transition metal film 3. The transparent dielectric film 4 is used as an antireflection layer and can reduce reflection of incident light.

The silicon-based room-temperature infrared hot-electron photodetector of the present invention has advantages such as wideband absorption, a simple structure, and a quick response speed, helps to improve the performance of a near infrared band photodetector, and can be applied to near infrared band imaging and communication.

A planar multi-layer structure is used as a wideband absorption device of a near infrared band, which is insensitive to polarization and insensitive to an incident angle, and has a large tolerance for the thickness error of a multi-layer film, so that requirements of processing technologies are not very high, preparation is easy, costs are low, and promotion and use are convenient.

Specifically, in this embodiment, the bottom conductive electrode 1 includes a titanium film, a gold film, and an aluminum film, the thickness of the titanium film is greater than 5 nm, the thickness of the gold film is greater than 40 nm, and the thickness of the aluminum film is greater than 30 nm. In one aspect, aluminum and silicon form an ohmic contact, and in another aspect, the electrode and the silicon thin film form a light reflector to improve the light absorption efficiency of transition metal.

Specifically, the material of the bottom conductive electrode 1 is selected from the group consisting of gold, silver, chromium, aluminum, a noble metal, a transition metal and any combination thereof.

Specifically, the silicon thin film 2 is a lightly doped N-type or P-type silicon thin film, the resistivity of the silicon thin film ranges from 0.1 Ω·cm to 100 Ω·cm, and the thickness of the silicon thin film 2 ranges from 10 nm to 5 μm. The thickness of the silicon thin film is only hundreds of nanometers, and is much smaller than a 500-μm thickness of a common silicon base, and the silicon thin film is also monocrystalline and lightly doped, which is conducive to the collection of electrons.

Specifically, the material of the transition metal film 3 is selected from the group consisting of gold, platinum, iron, chromium, titanium and any combination thereof. The thickness of the transition metal film ranges from 5 nm to 100 nm. The transition metal film has a thickness of only tens of nanometers, which is smaller than a mean free path of electrons, but can absorb most light.

Specifically, the material of the transparent dielectric film 4 is selected from the group consisting of magnesium fluoride, silicon nitride, silicon oxide, polymethyl methacrylate (PMMA) and any combination thereof. The thickness of the transparent dielectric film 4 ranges from 50 nm to 500 nm.

The specific structure of a photodetector prepared according to Embodiment 1 sequentially includes from bottom to top the bottom conductive electrode 1 being an aluminum metal film, the silicon thin film 2 being a P-type silicon thin film, the transition metal film 3 being a titanium metal film, and the transparent dielectric film 4 being PMMA. To verify the optical performance and the electrical performance of the photodetector, referring to FIG. 2, a sample is cut by using a focused ion beam system, and a cross-sectional SEM image is acquired. Through the observation of a cross section under the SEM, each layer of structure in the sample can be clearly seen.

The optical absorption rate and reflectivity of the sample are measured by using a spectrometer. Test results are shown in FIG. 3. The sample approaches full absorption and has a very low reflectivity in a near infrared band from 1200 nm to 2000 nm, to implement wideband absorption in the near infrared band.

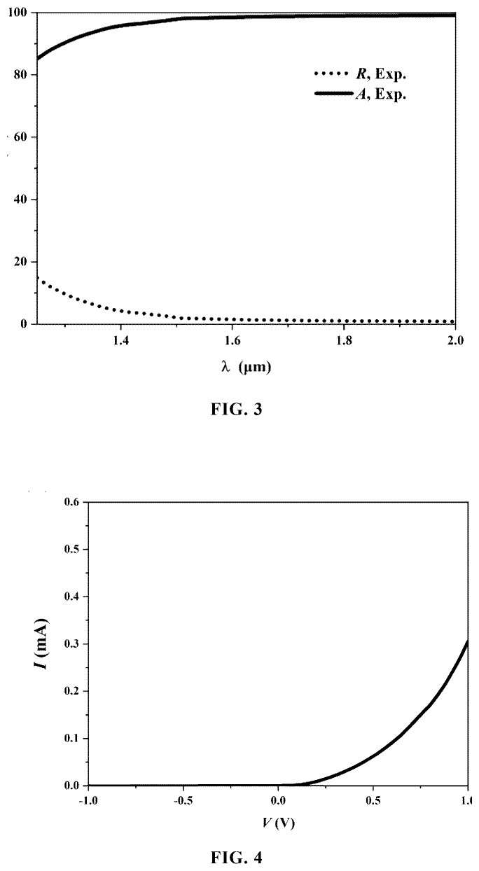

The electrical response of the sample is tested by using a micro-area test platform. As shown in FIG. 4, a current-voltage curve at a voltage from −1 V to 1 V is tested, and the result manifests a clear rectification effect.

Referring to FIG. 5, a photocurrent curve of the sample at different near infrared wavelengths during switching with time is shown at a wavelength from 1250 nm to 1800 nm at intervals of 50 nm. The sample manifests corresponding photoelectric responses throughout 1250 nm to 1800 nm.

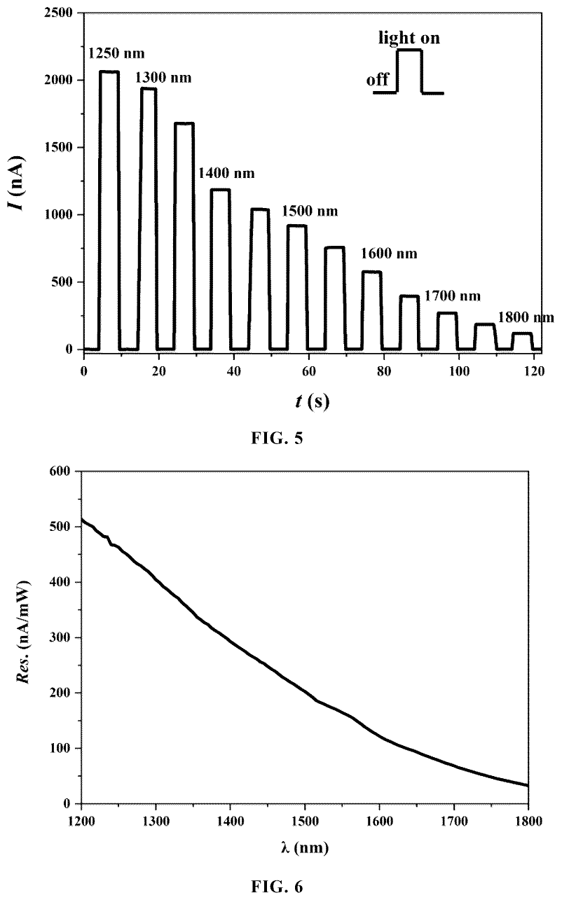

Photocurrents of the sample at smaller wavelength intervals and corresponding light powers of light output of a laser are measured. A responsivity curve of the sample in a near infrared band from 1200 nm to 1800 nm can be calculated, as shown in FIG. 6. The value of the highest responsivity has reached 513 nA/mW, and responses exist throughout the near infrared band from 1200 nm to 1800 nm. It indicates that the sample implements wideband absorption from 1200 nm to 1800 nm.

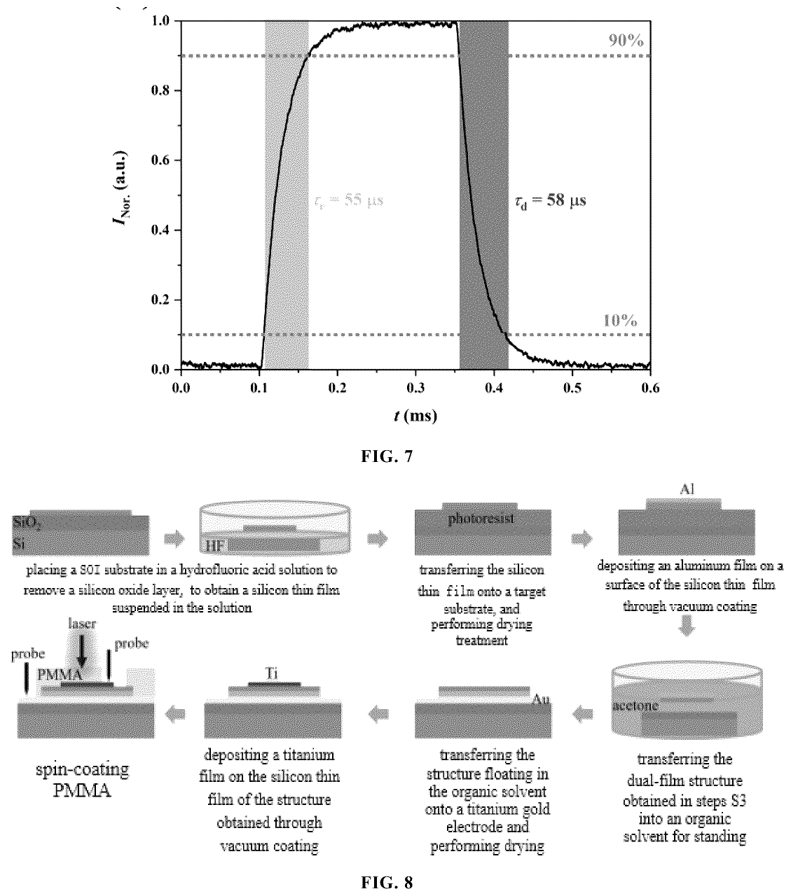

The response time of the sample is tested subsequently by using a 1310-nm single-mode laser. Referring to FIG. 7, the rising edge and the falling edge are respectively 55 μs and 58 μs, and the ultra-fast response speed is implemented.

### Embodiment 2

To obtain the silicon-based room-temperature infrared hot-electron photodetector in the foregoing Embodiment 1, referring to FIG. 8, this embodiment provides a method for preparing a silicon-based room-temperature infrared hot-electron photodetector, including the following steps:
S1. placing a SOI (Silicon-On-Insulator) substrate in a hydrofluoric acid solution to remove a silicon oxide layer to obtain a silicon thin film 2 suspended in the solution;
S2. transferring the silicon thin film 2 onto a target substrate, and performing drying treatment;
S3. depositing an aluminum film on the surface of the silicon thin film 2 through vacuum coating, to obtain a film structure;
S4. transferring the structure obtained in steps S3 into an organic solvent for standing;
S5. transferring the structure floating in the organic solvent onto a titanium gold electrode and performing drying;
S6. depositing a titanium film on the silicon thin film of the structure obtained in Step S5 through vacuum coating, where the titanium gold electrode and the aluminum film form a bottom conductive electrode 1 on one side of the silicon thin film 2, and the titanium film forms a transition metal film 3 on the other side of the silicon thin film 2;
S7. spin-coating at least one of magnesium fluoride, silicon nitride, silicon oxide and PMMA on the transition metal film 3 to form a transparent dielectric film 4.

Specifically, the foregoing steps are further described with reference to an embodiment:
(1) Perform ultrasonic cleaning on a commercial silicon on insulator (SOI) base by using acetone, ethanol, and deionized water, and place the SOI base in a hydrofluoric acid solution with a volume percentage of 40% to remove a silicon oxide layer, to obtain a silicon thin film suspended in the solution.
(2) Transfer the ultra-thin silicon thin film 2 to the surface of an organic substance soluble in an organic solvent, and perform drying.
(3) Deposit an aluminum metal film with a thickness of 30 nm on the surface of the ultra-thin silicon thin film by using an ion beam sputtering technique. Before film deposition, pre-sputtering is performed first for 5 min. The vacuum degree for deposition is 5×10⁻⁴ Pa. Parameters of ion beam sputtering include: the target material is an aluminum target, ion energy is 800 eV, the ion beam current is 70 mA, the neutralization current is 90 mA, argon is introduced during sputtering, and the cavity pressure is 0.02 Pa.
(4) Transfer the structure obtained in 3) into an organic solvent, and perform standing for a period of time.
(5) Transfer the structure suspended in the organic solvent onto the titanium gold electrode, and perform drying. The titanium gold electrode is prepared by using an electron beam evaporation method. Before film deposition, pre-sputtering is performed first for 5 min. Parameters of electron beam evaporation include: the target material is a titanium target or a gold target, the evaporation rate is 0.5 A/s, the pre-evaporation power is 30%, the evaporation power is 30%, the working vacuum is 5×10⁻⁴ Pa, and the working temperature is 20 degrees.
(6) Uniformly applying a layer of photoresist on the surface of the sample obtained by the processing in Step 5, expose a window smaller than the silicon thin film by using an ultraviolet exposure system, then deposit a titanium metal film with a thickness of 20 nm by using an electron beam evaporation technique, subsequently immerse the device in an acetone solution, perform standing for a period time, take out the device, and perform drying. Before film deposition, pre-sputtering is performed first for 5 min. Parameters of electron beam evaporation include: the target material is a titanium target, the evaporation rate is 0.5 A/s, the pre-evaporation power is 30%, the evaporation power is 30%, the working vacuum is 5×10⁻⁴ Pa, and the working temperature is 20 degrees.
(7) Spin-coat PMMA with a thickness of 260 nm on the surface of the obtained device, and expose two windows by using an electron beam exposure system, where the two windows are respectively located on the surface of titanium and the surface of the gold electrode.

The deposition process is strictly controlled during the foregoing deposition, including a sputtering pressure, a base vacuum degree, ion energy, a sputtering rate, and the like, to ensure a uniform and consistent thickness in each time of deposition.

### Embodiment 3

Based on the foregoing Embodiment 1 and Embodiment 2, the present invention further discloses an application mode of a photodetector. The photodetector of the present invention is applied to optical communication and near infrared imaging. To achieve such an effect, in the present invention, applications of the photodetector to optical communication and near infrared imaging are respectively tested.

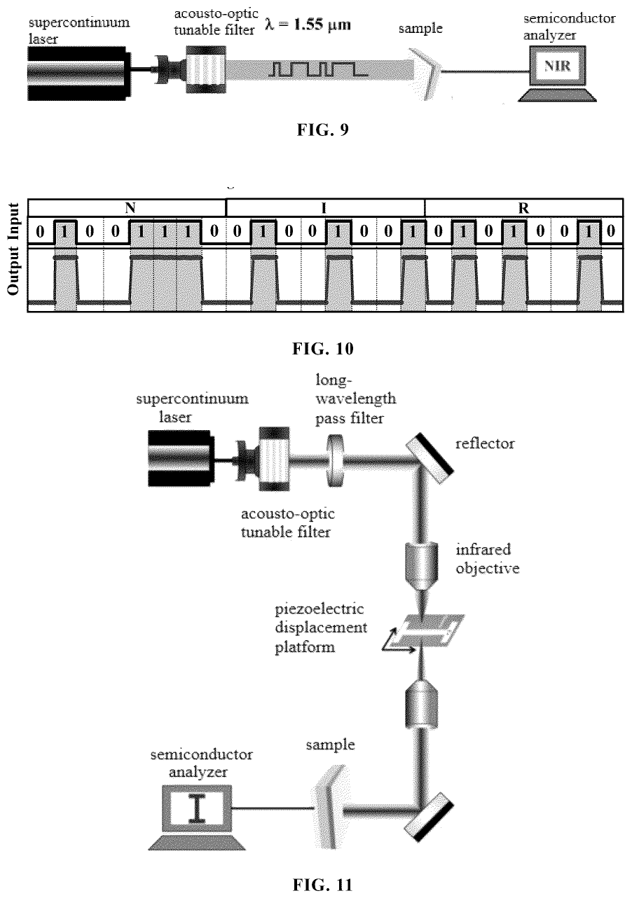

Referring to FIG. 9 and FIG. 10, an optical communication test is performed on the sample in Embodiment 1. The test platform is shown in FIG. 9. After white light emitted by a supercontinuum laser passes through an acousto-optic tunable filter, light with a wavelength of 1550 nm is left. The sample in Embodiment 1 is irradiated by the light, and then a probe connected to a semiconductor analyzer is placed on the sample in Embodiment 1. Through a switch that controls light output of the supercontinuum laser, when the laser outputs light, the sample can generate a photocurrent.

Comparison between a photocurrent measured by the semiconductor analyzer and a light output signal of the supercontinuum laser is shown in FIG. 10. An acousto-optic filter encodes and controls an output of the supercontinuum laser. Transmitted characters are encoded using the ASCII binary system and loaded into infrared light to be irradiated to a device. The photocurrent signal measured by the semiconductor analyzer adequately converts an optical signal into an electrical signal, to implement demodulation of the loaded information.

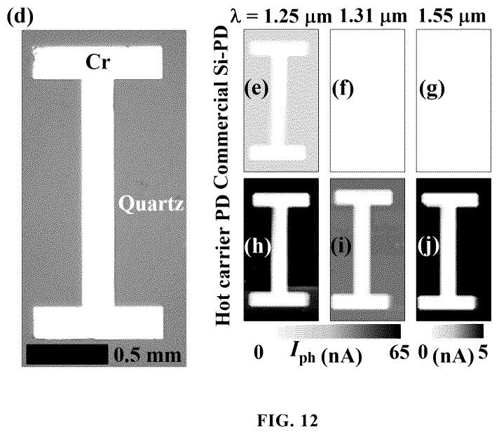

Referring to FIG. 11 and FIG. 12, an imaging test in a near infrared band is performed on the sample in Embodiment 1. The imaging test system in a near infrared band is shown in FIG. 11. Light outputted by the supercontinuum laser passes through the acousto-optic tunable filter, and then passes through one long-wavelength pass filter to filter out light below 1100 nm. The laser light then passes through a reflector to enter a to-be-imaged object. A Mitutoyo infrared objective with a zoom ratio of 50 is used to focus a spot. A piezoelectric displacement platform is used to control the movement of the to-be-imaged object. A Mitutoyo infrared objective with a zoom ratio of 20 is used to focus a spot. The laser light passes through a reflector to enter the sample in Embodiment 1. The sample in Embodiment 1 is pricked by the probe connected to the semiconductor analyzer.

The to-be-imaged object is shown in FIG. 12. Cr is coated on a quartz plate, and the blank region is a transparent region. Laser light of 1250 nm, laser light of 1310 nm, and laser light of 1550 nm are respectively used to perform imaging on the sample in Embodiment 1 and a commercial silicon detector. FIG. e, FIG. f, and FIG. g show imaging results of the commercial silicon detector at 1250 nm, 1310 nm, and 1550 nm respectively. FIG. h, FIG. 1, and FIG. j show imaging results of the photodetector in Embodiment 1 at 1250 nm, 1310 nm, and 1550 nm, respectively. FIG. e, FIG. f, FIG. h, and FIG. 1 have the same color scale, FIG. g and FIG. j are at the same color scale, and a color scale diagram is provided below correspondingly.

As can be seen from the comparison of test results, the sample in Embodiment 1 manifests a larger photocurrent under illumination with the same power, and therefore has a better imaging effect than the commercial silicon detector.

Obviously, the foregoing embodiments are merely examples for clear description, rather than a limitation to implementations. For a person of ordinary skill in the art, other changes or variations in different forms may also be made based on the foregoing description. All implementations cannot and do not need to be exhaustively listed herein. Obvious changes or variations that are derived there from still fall within the protection scope of the invention of the present invention.

What is claimed is:

1. A silicon-based room-temperature infrared hot-electron photodetector, comprising a base and a planar multi-layer structure disposed on the base, wherein the planar multi-layer structure comprises:
a bottom conductive electrode;
a silicon thin film, disposed on the bottom conductive electrode, wherein the bottom conductive electrode and the silicon thin film form an ohmic contact and constitute an optical reflector;
a transition metal film, disposed on the silicon thin film, wherein the silicon thin film and the transition metal film form a Schottky contact, a thickness of the silicon thin film is smaller than a depletion layer width of a Schottky junction formed by a silicon substrate and the transition metal film, the transition metal film absorbs near infrared light and generates hot electrons to be injected into the silicon thin film, and the hot electrons are collected by the bottom conductive electrode to form a photocurrent; and
a transparent dielectric film, disposed on the transition metal film, wherein the transparent dielectric film is used as an antireflection layer and capable of reducing reflection of incident light.

2. The silicon-based room-temperature infrared hot-electron photodetector according to claim 1, wherein the bottom conductive electrode comprises a titanium film, a gold film, and an aluminum film, a thickness of the titanium film is greater than 5 nm, a thickness of the gold film is greater than 40 nm, and a thickness of the aluminum film is greater than 30 nm.

3. The silicon-based room-temperature infrared hot-electron photodetector according to claim 1, wherein a material of the bottom conductive electrode is selected from the group consisting of gold, silver, chromium, aluminum, a noble metal, a transition metal and any combination thereof.

4. The silicon-based room-temperature infrared hot-electron photodetector according to claim 1, wherein the silicon thin film is a lightly doped N-type or P-type silicon thin film, a resistivity of the silicon thin film ranges from 0.1 Ω·cm to 100 Ω·cm, and the thickness of the silicon thin film ranges from 10 nm to 5 μm.

5. The silicon-based room-temperature infrared hot-electron photodetector according to claim 1, wherein a material of the transition metal film is selected from the group consisting of gold, platinum, iron, chromium, titanium and any combination thereof.

6. The silicon-based room-temperature infrared hot-electron photodetector according to claim 1, wherein a thickness of the transition metal film ranges from 5 nm to 100 nm.

7. The silicon-based room-temperature infrared hot-electron photodetector according to claim 1, wherein a material of the transparent dielectric film is selected from the group consisting of magnesium fluoride, silicon nitride, silicon oxide, PMMA and any combination thereof.

8. The silicon-based room-temperature infrared hot-electron photodetector according to claim 1, wherein a thickness of the transparent dielectric film ranges from 50 nm to 500 nm.

9. A method for preparing a silicon-based room-temperature infrared hot-electron photodetector, comprising steps of:
S1: placing a SOI substrate in a hydrofluoric acid solution to remove a silicon oxide layer, to obtain a silicon thin film suspended in the solution;
S2: transferring the silicon thin film onto a target substrate, and performing drying treatment;
S3: depositing an aluminum film on a surface of the silicon thin film through vacuum coating, to obtain a dual-film structure consisting of the aluminum and silicon thin films;
S4: transferring the dual-film structure obtained in steps S3 into an organic solvent for standing;
S5: transferring the structure floating in the organic solvent onto a titanium gold electrode and performing drying;
S6: depositing a titanium film on the silicon thin film of the structure obtained in Step S5 through vacuum coating, wherein the titanium gold electrode and the aluminum film form a bottom conductive electrode on one side of the silicon thin film, and the titanium film forms a transition metal film on the other side of the silicon thin film; and
S7: spin-coating at least one of magnesium fluoride, silicon nitride, silicon oxide and PMMA on the transition metal film to form a transparent dielectric film.

10. Use of a silicon-based room-temperature infrared hot-electron photodetector, wherein the silicon-based room-temperature infrared hot-electron photodetector according to claim 1 is used, and the photodetector is applied to optical communication and near infrared imaging.
